(19) United States
(12) Patent Application Publication
(10) Pub. No.: US 2020/0044133 A1
(43) Pub. Date: Feb. 6, 2020

(54) THERMOELECTRIC MODULE AND THERMOELECTRIC GENERATOR

(71) Applicant: LG CHEM, LTD., Seoul (KR)

(72) Inventors: Dong Sik KIM, Daejeon (KR); Byung Kyu LIM, Daejeon (KR); Jaeki LEE, Daejeon (KR); Cheol Hee PARK, Daejeon (KR)

(73) Assignee: LG CHEM, LTD., Seoul (KR)

(21) Appl. No.: 16/341,351

(22) PCT Filed: Aug. 20, 2018
(86) PCT No.: PCT/KR2018/009541

§ 371 Date: Apr. 11, 2019

(30) Foreign Application Priority Data
Aug. 18, 2017 (KR) 10-2017-0105104

(51) Int. Cl. H01L 35/32; H01L 35/08; H01L 35/16; H01L 35/18

(52) U.S. Cl. CPC H01L 35/32; H01L 35/18; H01L 35/16; H01L 35/08

(57) ABSTRACT

A thermoelectric module and a thermoelectric generator, the thermoelectric module includes a first substrate provided with a first electrode, a second substrate provided with a second electrode and disposed opposite to the first substrate, and a plurality of thermoelectric elements disposed between the first substrate and the second substrate and electrically connected to the first electrode and the second electrode. The thermoelectric elements may be sintered and bonded to each other with bonding layers containing silver (Ag) to be electrically connected between the first substrate and the second substrate, and may include Skutterudite-based thermoelectric elements electrically connected to the first electrode and BiTe-based thermoelectric elements connected to the Skutterudite-based thermoelectric elements with the bonding layers and electrically connected to the second electrode.

### TECHNICAL FIELD

This application claims priority to and the benefit of Korean Patent Application No. 10-2017-0105104 filed in the Korean Intellectual Property Office on Aug. 18, 2017, the entire contents of which are incorporated herein by reference.

The present invention relates to a thermoelectric module and a thermoelectric generator in which quality and thermal stability of the thermoelectric module are improved.

### BACKGROUND ART

When there is a temperature difference between opposite ends of a solid-state material, there is generated a difference in concentration of carriers (electrons or holes) having a heat dependence, which appears as an electric phenomenon called thermo-electromotive force, that is, a thermoelectric phenomenon.

The thermoelectric phenomenon refers to a direct energy conversion between the temperature difference and electric voltage.

The thermoelectric phenomenon may be classified into a thermoelectric generation which generates electric energy and a thermoelectric cooling/heating which causes the temperature difference at the opposite ends of the material by power supply.

A thermoelectric material which exhibits the thermoelectric phenomenon, i.e. a thermoelectric semiconductor, has been studied in many ways because the material has advantages of being environmentally friendly and sustainable in processes of power generation and cooling.

Furthermore, interest in such a thermoelectric material is further increasing because the material may directly produce power from industrial waste heat and automobile waste heat, and may thus be used in technology useful for fuel efficiency improvement and CO₂ reduction.

A basic unit of a thermoelectric module may be a uni-couple of p-n thermoelectric elements including a p-type thermoelectric element (TE) through which a current flows by a hole carrier and an n-type thermoelectric element through which a current flows by an electron. The thermoelectric module may also include an electrode which connect the p-type thermoelectric element and the n-type thermoelectric element with each other.

The thermoelectric element may be generally formed in a rod-like or columnar structure, and the power proportional to the square of the temperature difference may be obtained in a state in which one end of the material is maintained to be at a high temperature and the other end thereof is maintained to be at a low temperature.

The thermoelectric material used for such a thermoelectric element has a use temperature range in which a performance thereof is optimized, and a plurality of thermoelectric materials are bonded and used to follow the temperature difference in order to maximize power generation output or efficiency at the use temperature. Here, an element formed by bonding the thermoelectric materials to each other in series both mechanically structurally and electrically is called a segment thermoelectric element.

Meanwhile, sintering temperatures of a Skutterudite-based thermoelectric material and a BiTe-based thermoelectric material are different from each other. The quality and thermal stability of the thermoelectric module may thus be deteriorated in a process of manufacturing the thermoelectric element by bonding the above thermoelectric materials to each other.

### DISCLOSURE

### Technical Problem

The present invention has been made in an effort to provide a thermoelectric module and a thermoelectric generator having advantages of improved output, efficiency characteristic and thermal stability.

### Technical Solution

An exemplary embodiment of the present invention provides: a first substrate provided with a first electrode; a second substrate provided with a second electrode and disposed opposite to the first substrate; and a plurality of thermoelectric elements disposed between the first substrate and the second substrate and electrically connected to the first electrode and the second electrode.

The thermoelectric elements may be sintered and bonded to each other with bonding layers containing silver (Ag) to be electrically connected between the first substrate and the second substrate, and include Skutterudite-based thermoelectric elements electrically connected to the first electrode and BiTe-based thermoelectric elements connected to the Skutterudite-based thermoelectric elements with the bonding layers and electrically connected to the second electrode.

The thermoelectric elements may include first thermoelectric elements electrically connected between the first substrate and the second substrate, and second thermoelectric elements electrically connected between the first substrate and the second substrate in a state in which the second thermoelectric elements are spaced apart from the first thermoelectric elements.

The first thermoelectric elements may be formed of at least two or more thermoelectric elements bonded to each other with the bonding layer.

The first thermoelectric elements may include a first Skutterudite-based thermoelectric element electrically connected to the first electrode and a first

BiTe-based thermoelectric element connected to the first Skutterudite-based thermoelectric element with the bonding layer and electrically connected to the second electrode.

Opposite ends of the first thermoelectric elements may each be electrically connected to the first electrode and the second electrode with the bonding layers.

The second thermoelectric elements may be formed of at least two or more thermoelectric elements bonded to each other with the bonding layer.

The second thermoelectric elements may include a second Skutterudite-based thermoelectric element electrically connected to the first electrode and a second BiTe-based thermoelectric element connected to the second Skutterudite-based thermoelectric element with the bonding layer and electrically connected to the second electrode.

Opposite ends of the second thermoelectric elements may each be electrically connected to the first electrode and the second electrode with the bonding layers.

The first thermoelectric elements may be p-type thermoelectric semiconductors, and the second thermoelectric elements may be n-type thermoelectric semiconductors.

The thermoelectric module may further include a diffusion barrier layer disposed between the first substrate and the first thermoelectric elements.

The thermoelectric module may further include a diffusion barrier layer disposed between the second substrate and the second thermoelectric elements.

The thermoelectric module may further include a diffusion barrier layer disposed between the first Skutterudite-based thermoelectric element and the first BiTe-based thermoelectric element.

The thermoelectric module may further include a diffusion barrier layer disposed between the second Skutterudite-based thermoelectric element and the second BiTe-based thermoelectric element.

The diffusion barrier layer may be formed of at least one selected from the group consisting of hafnium (Hf), titanium nitride (TiN), zirconium (Zr), and Mo—Ti.

According to an embodiment of the present invention, a thermoelectric generator may include the thermoelectric module as described above. The thermoelectric generator may include at least one high temperature block connected to the thermoelectric module, a low temperature block connected to the thermoelectric module at a side surface opposite to the high temperature block, and a heat dissipating member disposed in the high temperature block and the low temperature block.

### Advantageous Effects

According to an embodiment of the present invention, output, efficiency characteristic and thermal stability of the thermoelectric module may be improved by sintering and bonding the first thermoelectric elements to each other and the second thermoelectric elements to each other, using a paste containing silver (Ag).

According to an embodiment of the present invention, the output and efficiency characteristic of the thermoelectric module may be improved, so that the power generation output and efficiency of the thermoelectric generator may be improved.

### DESCRIPTION OF THE DRAWINGS

FIG. 1 is a cross-sectional view schematically showing main components of a uni-couple of a thermoelectric module according to an embodiment of the present invention.

FIG. 2 is a schematic view illustrating an output characteristic of the thermoelectric module according to an embodiment of the present invention.

FIG. 3 is a schematic view illustrating efficiency characteristic of the thermoelectric module according to an embodiment of the present invention.

### MODE FOR INVENTION

Hereinafter, embodiments of the present invention are described in detail with reference to the accompanying drawings so that those skilled in the art may easily practice the present invention. As those skilled in the art would realize, the described embodiments may be modified in various different ways, all without departing from the spirit or scope of the present invention.

The drawings and description are to be regarded as illustrative in nature and not restrictive. Like reference numerals designate like elements throughout the specification.

Throughout this specification and the claims that follow, when it is described that an element is “coupled” to another element, the element may be “directly coupled” to the other element or “indirectly coupled” to the other element through a third member. In addition, unless explicitly described to the contrary, the word “comprise” and variations such as “comprises” or “comprising”, will be understood to imply the inclusion of stated elements but not the exclusion of any other elements.

Throughout this specification and the claims that follow, when it is described that an element such as a layer, a film, a region, a plate or the like is referred to as being “on” or “above” another element, it is to be understood that the element may be directly “on” another element or “above” another element including other elements therebetween. In addition, the word “on” or “above” means to be located above or below the object portion and does not necessarily mean that the object is located on the upper side with respect to the gravitational direction.

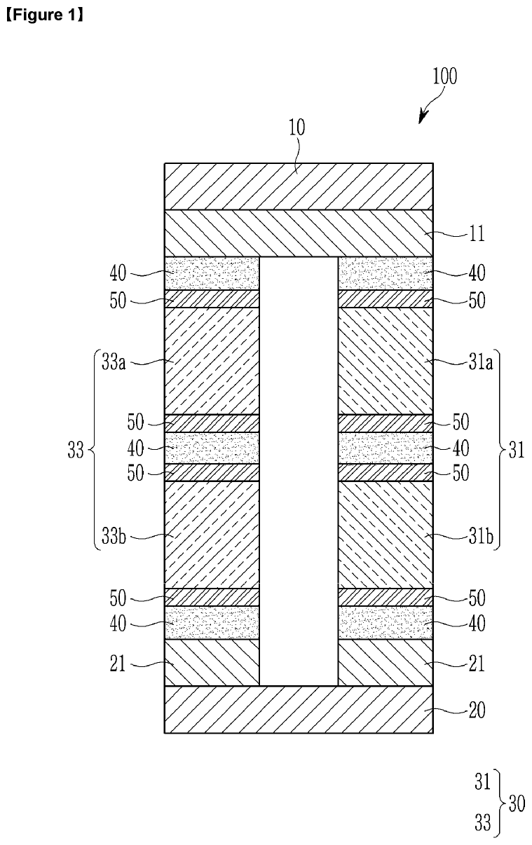

FIG. 1 is a cross-sectional view schematically showing main components of a uni-couple of a thermoelectric module according to an embodiment of the present invention.

According to an embodiment of the present invention, as shown in FIG. 1, a uni-couple 100 of a thermoelectric module may include: a first substrate 10 provided with a first electrode 11; a second substrate 20 provided with a second electrode 21 and disposed opposite to the first substrate 10; and a plurality of thermoelectric elements 30 disposed between the first substrate 10 and the second substrate 20 and electrically connected to the first electrode 11 and the second electrode 21. Here, the thermoelectric elements 30 may be bonded to each other with bonding layers 40 containing silver (Ag).

The thermoelectric elements 30 may include Skutterudite-based thermoelectric elements 31a and 33a electrically connected to the first electrode 11, and BiTe-based thermoelectric elements 31b and 33b connected to the Skutterudite-based thermoelectric elements 31a and 33a with the bonding layers 40 and electrically connected to the second electrode.

The Skutterudite-based thermoelectric elements 31a and 33a may include a first Skutterudite-based thermoelectric element 31a and a second Skutterudite-based thermoelectric element 33a, and the BiTe-based thermoelectric elements 31b and 33b may include a first BiTe-based thermoelectric element 31b and a second BiTe-based thermoelectric element 33b.

Meanwhile, the first substrate 10 and the second substrate 20 may be respectively disposed on opposite ends of the thermoelectric elements 30, having the thermoelectric elements 30 interposed therebetween, to support the thermoelectric elements.

The first substrate 10 may be used as a high-temperature portion in the present embodiment. The first substrate 10 has a flat surface facing the thermoelectric elements 30 and may stably support the thermoelectric elements 30.

The first substrate 10 may be formed of a ceramic material such as alumina or aluminum nitride (AlN).

The second substrate 20 may be used as a low-temperature portion in the present embodiment. The second substrate 20 may be disposed opposite to the first substrate 10 having the thermoelectric elements 30 interposed therebetween and stably support the thermoelectric elements 30 together with the first substrate 10

The second substrate 20 may be formed of a ceramic material such as alumina or AlN.

A heat dissipating member (not shown) may also be formed on the second substrate 20 to improve heat dissipation efficiency.

Meanwhile, the thermoelectric elements 30 may be disposed in a state in which the thermoelectric elements 30 are electrically connected between the first substrate 10 and the second substrate 20 by the first electrode 11 and the second electrode 21.

The thermoelectric elements 30 may include first thermoelectric elements 31 electrically connected between the first substrate 10 and the second substrate 20 and second thermoelectric elements 33 electrically connected between the first substrate 10 and the second substrate 20 in a state in which the second thermoelectric elements 33 are spaced apart from the first thermoelectric elements 31.

The first thermoelectric elements 31 may be formed of at least two or more thermoelectric elements bonded to each other with the bonding layer 40 and disposed between the first substrate 10 and the second substrate 20. Opposite ends of the first thermoelectric elements 31 may each be electrically connected to the first electrode 11 and the second electrode 21 with bonding layers 40.

The first thermoelectric elements 31 may be formed of p-type thermoelectric semiconductors and include a first Skutterudite-based thermoelectric element 31a electrically connected to the first electrode 11 and a first BiTe-based thermoelectric element 31b electrically connected to the second electrode 21.

That is, the first thermoelectric elements 31 may have a first Skutterudite-based thermoelectric element 31a that maximizes performance efficiency at a relatively high temperature region in a portion electrically connected to the first substrate 10.

The first thermoelectric elements 31 may have a first BiTe-based thermoelectric element 31b that maximizes performance efficiency at a relatively low temperature region in a portion electrically connected to the second substrate 20.

In the first thermoelectric elements 31, the first skutertudite-based thermoelectric element 31a and the first BiTe-based thermoelectric element 31b may be bonded to each other with the bonding layer 40.

That is, the bonding layer 40 formed of a paste containing silver (Ag) may sinter and bond the first Skutterudite-based thermoelectric element 31a and the first BiTe-based thermoelectric element 31b to each other.

Here, the first Skutterudite-based thermoelectric element 31a and the first BiTe-based thermoelectric elements 31b may be sintered and bonded to each other with the bonding layer 40 before being electrically connected to the first substrate 10 and the second substrate 20

Meanwhile, the thermoelectric module may further include a diffusion barrier layer 50 disposed between the first Skutterudite-based thermoelectric element 31a and the first BiTe-based thermoelectric element 31b.

A diffusion barrier layer 50 may prevent thermoelectric materials from diffusing to each other.

A diffusion barrier layer 50 may be formed of at least one selected from the group consisting of hafnium (Hf), titanium nitride (TiN), zirconium (Zr), and Mo—Ti.

In addition to the diffusion barrier layer 50 formed between the first Skutterudite-based thermoelectric element 31a and the first BiTe-based thermoelectric element 31b as described above, the thermoelectric module may further include a diffusion barrier layer formed between the first substrate 10 and the first thermoelectric elements 31 and a diffusion barrier layer formed between the second substrate 20 and the first thermoelectric elements 31.

The second thermoelectric elements 33 may be formed in a shape identical or similar to that of the first thermoelectric elements 31, and may be disposed between the first substrate 10 and the second substrate 20 in a state in which the second thermoelectric elements 33 are spaced apart from the first thermoelectric elements 31.

The second thermoelectric elements 33 may also be adapted to have an appropriate size or shape to improve power generation efficiency. The second thermoelectric elements 33 may be formed of n-type thermoelectric semiconductors and include a second Skutterudite-based thermoelectric element 33a electrically connected to the first electrode 11 and a second BiTe-based thermoelectric element 33b electrically connected to the second electrode 21.

That is, the second thermoelectric elements 33 may have a second Skutterudite-based thermoelectric element 33a that maximizes performance efficiency at a relatively high temperature region in a portion electrically connected to the first substrate 10.

The second thermoelectric elements 33 may have a second BiTe-based thermoelectric element 31b that maximizes performance efficiency at a relatively low temperature region in a portion electrically connected to the second substrate 20.

In the second thermoelectric elements 33, the second skutertudite-based thermoelectric element 33a and the second BiTe-based thermoelectric element 33b may be bonded to each other with the bonding layer 40.

That is, the bonding layer 40 formed of a paste containing silver (Ag) may sinter and bond the second Skutterudite-based thermoelectric element 33a and the second BiTe-based thermoelectric element 33b to each other.

Here, the second Skutterudite-based thermoelectric element 33a and the second BiTe-based thermoelectric element 33b may be sintered and bonded to each other with the bonding layer 40 before being electrically connected to the first substrate 10 and the second substrate 20.

Meanwhile, the thermoelectric module may further include a diffusion barrier layer 50 disposed between the second Skutterudite-based thermoelectric element 33a and the second BiTe-based thermoelectric element 33b.

A diffusion barrier layer 50 may prevent the thermoelectric materials from diffusing to each other. In addition to the diffusion barrier layer 50 formed between the second Skutterudite-based thermoelectric element 33a and the second BiTe-based thermoelectric element 33b as described above, the thermoelectric module may further include a diffusion barrier layer formed between the first substrate 10 and the second thermoelectric elements 33 and a diffusion barrier layer formed between the second substrate 20 and the second thermoelectric elements 33.

As described above, the uni-couple 100 of the thermoelectric module of the present embodiment may improve the output, efficiency characteristic and thermal stability of the thermoelectric module by sintering and bonding the first thermoelectric elements to each other and the second thermoelectric elements to each other, using a paste containing silver (Ag).

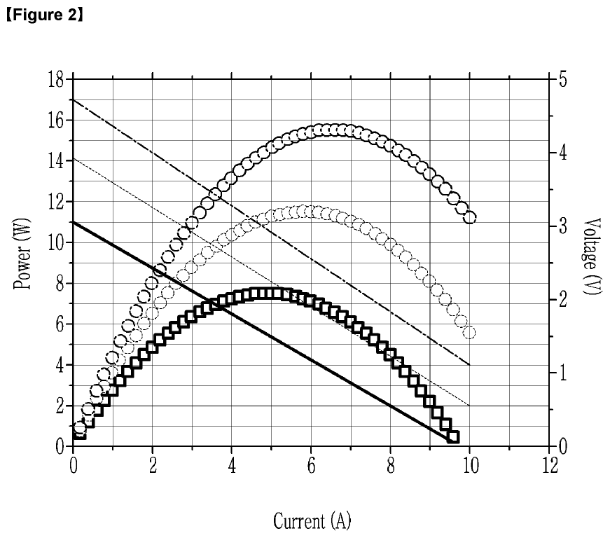

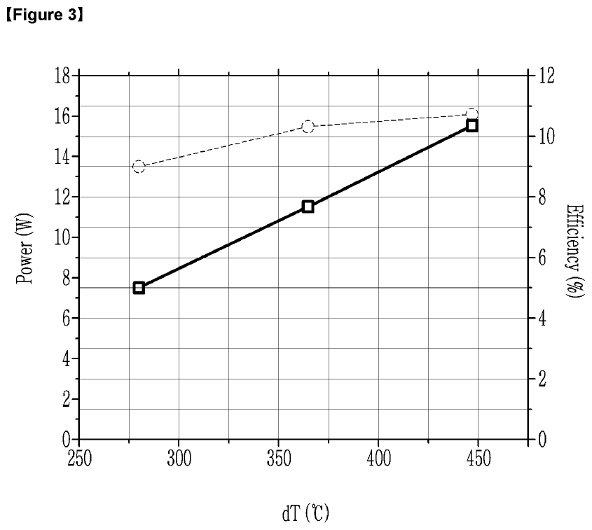

FIG. 2 is a schematic view illustrating an output characteristic of the thermoelectric module according to an embodiment of the present invention; and FIG. 3 is a schematic view illustrating efficiency characteristic of the thermoelectric module according to an embodiment of the present invention.

That is, FIGS. 2 and 3 are graphs showing the output and efficiency characteristic of a segment module depending on a temperature difference after manufacturing the thermoelectric module constituted by 31 uni-couples 100 of the thermoelectric module.

To be specific, as shown in FIG. 2, the power generation output of 7.49 W, 11.52 W, and 15.54 W is obtained at 281° C., 356° C., and 447° C., respectively.

Here, Voc (open circuit voltage) is 3.06V, 3.94V, and 4.73V at each temperature difference.

As shown in FIG. 3, high efficiency of 8.99%, 10.32%, or 10.72% is obtained in each temperature difference as a result of measuring the power generation efficiency.

In general, power generation efficiency of the Skutterudite-based thermoelectric elements is about 6.5% and therefore, the segment thermoelectric element is confirmed to have considerably high power generation efficiency.

According to an embodiment of the present invention, a thermoelectric generator may include at least one high temperature block connected to the thermoelectric module, a low temperature block connected to the thermoelectric module at a side surface opposite to the high temperature block, and a heat dissipating member disposed in the low temperature block.

The output and efficiency characteristic of the thermoelectric module are thus improved, so that the power generation efficiency of the thermoelectric generator may be improved.

While this invention has been described in connection with what is s presently considered to be practical exemplary embodiments, it is to be understood that the invention is not limited to the disclosed embodiments. On the contrary, it is intended to cover various modifications and equivalent arrangements included within the spirit and scope of the appended claims.

<Description of symbols>

| | |
|---|---|
| 10: first substrate | 11: first electrode |
| 20: second substrate | 30: thermoelectric elements |
| 31: first thermoelectric elements | 33: second thermoelectric elements |
| 40: bonding layer | 50: diffusion barrier layer |

1. A thermoelectric module comprising:
a first substrate provided with a first electrode;
a second substrate provided with a second electrode and disposed opposite to the first substrate; and
a plurality of thermoelectric elements disposed between the first substrate and the second substrate and electrically connected to the first electrode and the second electrode,
wherein the thermoelectric elements are sintered and bonded to each other with bonding layers containing silver (Ag) to be electrically connected between the first substrate and the second substrate, and include Skutterudite-based thermoelectric elements electrically connected to the first electrode and BiTe-based thermoelectric elements connected to the Skutterudite-based thermoelectric elements with the bonding layers and electrically connected to the second electrode.

2. The thermoelectric module of claim 1, wherein:
the thermoelectric elements include:
first thermoelectric elements electrically connected between the first substrate and the second substrate, and
second thermoelectric elements electrically connected between the first substrate and the second substrate in a state in which the second thermoelectric elements are spaced apart from the first thermoelectric elements.

3. The thermoelectric module of claim 2, wherein:
the first thermoelectric elements are formed of at least two or more of the thermoelectric elements bonded to each other with the bonding layer.

4. The thermoelectric module of claim 3, wherein the first thermoelectric elements include a first Skutterudite-based thermoelectric element, of the Skutterudite-based thermoelectric elements, electrically connected to the first electrode and a first BiTe-based thermoelectric element, of the BiTe-based thermoelectric elements, connected to the first Skutterudite-based thermoelectric element with the bonding layer and electrically connected to the second electrode.

5. The thermoelectric module of claim 3, wherein opposite ends of the first thermoelectric elements are each electrically connected to the first electrode and the second electrode with the bonding layers.

6. The thermoelectric module of claim 2, wherein
the second thermoelectric elements are formed of at least two or more of the thermoelectric elements bonded to each other with the bonding layer.

7. The thermoelectric module of claim 6, wherein:
the second thermoelectric elements include a second Skutterudite-based thermoelectric element, of the Skutterudite-based thermoelectric elements, electrically connected to the first electrode and a second BiTe-based thermoelectric element, of the BiTe-based thermoelectric elements, connected to the second Skutterudite-based thermoelectric element with the bonding layer and electrically connected to the second electrode.

8. The thermoelectric module of claim 6, wherein:
opposite ends of the second thermoelectric elements are each electrically connected to the first electrode and the second electrode with the bonding layers.

9. The thermoelectric module of claim 2, wherein:
the first thermoelectric elements are p-type thermoelectric semiconductors, and the second thermoelectric elements are n-type thermoelectric semiconductors.

10. The thermoelectric module of claim 2, further comprising
a diffusion barrier layer disposed between the first substrate and the first thermoelectric elements.

11. The thermoelectric module of claim 10, further comprising
a diffusion barrier layer disposed between the second substrate and the second thermoelectric elements.

12. The thermoelectric module of claim 4, further comprising
a diffusion barrier layer disposed between the first Skutterudite-based thermoelectric element and the first BiTe-based thermoelectric element.

13. The thermoelectric module of claim 7, further comprising
a diffusion barrier layer disposed between the second Skutterudite-based thermoelectric element and the second BiTe-based thermoelectric element.

14. The thermoelectric module of claim 10, wherein
the diffusion barrier layer is formed of
at least one selected from the group consisting of hafnium (Hf), titanium nitride (TiN), zirconium (Zr), and Mo—Ti.

15. A thermoelectric generator comprising the thermoelectric module of claim 1.

16. The thermoelectric generator of claim 15, further comprising
at least one high temperature block connected to the thermoelectric module, a low temperature block connected to the thermoelectric module at a side surface opposite to the high temperature block, and a heat dissipating member disposed in the high temperature block and the low temperature block.
